(19) United States
(12) Patent Application Publication
(10) Pub. No.: US 2017/0207313 A1
(43) Pub. Date: Jul. 20, 2017

(54) NANOWIRE METAL-OXIDE SEMICONDUCTOR (MOS) FIELD-EFFECT TRANSISTORS (FETs) (MOSFETs) EMPLOYING A NANOWIRE CHANNEL STRUCTURE EMPLOYING RECESSED CONDUCTIVE STRUCTURES FOR CONDUCTIVELY COUPLING NANOWIRE STRUCTURES

(71) Applicant: QUALCOMM Incorporated, San Diego, CA (US)

(72) Inventors: Stanley Seungchul Song, San Diego, CA (US); Jeffrey Junhao Xu, San Diego, CA (US); Kern Rim, San Diego, CA (US); Da Yang, San Diego, CA (US); Peijie Feng, San Diego, CA (US); Choh Fei Yeap, San Diego, CA (US)

(21) Appl. No.: 15/213,879

(22) Filed: Jul. 19, 2016

Related U.S. Application Data
(60) Provisional application No. 62/279,217, filed on Jan. 15, 2016.

(51) Int. Cl. H01L 29/423; H01L 29/66; H01L 29/78

(52) U.S. Cl. CPC H01L 29/42392; H01L 29/785; H01L 29/66795

(57) ABSTRACT

Nanowire metal-oxide semiconductor (MOS) Field-Effect Transistors (FETs) (MOSFETs) employing a nanowire channel structure employing recessed conductive structures for conductively coupling nanowire structures are disclosed. Conductive structures are disposed between adjacent nanowire structures to conductively couple nanowire structures. Providing conductive structures in the nanowire channel structure increases the average cross-sectional area of nanowire structures, as compared to a similar nanowire channel structure not employing conductive structures, thus increasing effective channel width and drive strength for a given channel structure height. The precision of a gate material filling process is also eased, because gate material does not have to be disposed in areas between adjacent nanowire structures occupied by conductive structures. The conductive structure width can also be recessed with regard to width of nanowire structures in the nanowire channel structure to allow for a thicker metal gate to lower the gate resistance, while providing excellent electrostatic gate control of the channel.

### PRIORITY APPLICATION

The present application claims priority under 35 U.S.C. §119(e) to U.S. Provisional Patent Application Ser. No. 62/279,217 filed on Jan. 15, 2016, and entitled “NANOWIRE METAL-OXIDE SEMICONDUCTOR (MOS) FIELD-EFFECT TRANSISTORS (FETs) (MOSFETs) EMPLOYING A NANOWIRE CHANNEL STRUCTURE EMPLOYING CONDUCTIVELY COUPLED NANOWIRE STRUCTURES,” the contents of which is incorporated herein by reference in its entirety.

### BACKGROUND

I. Field of the Disclosure

The technology of the disclosure relates generally to metal-oxide semiconductor (MOS) Field-Effect Transistors (FETs) (MOSFETs), and more particularly to the use of nanowire channels (e.g., silicon nanowires) in MOSFETs for short channel control.

II. Background

Transistors are essential components in modern electronic devices. Large numbers of transistors are employed in integrated circuits (ICs) in many modern electronic devices. For example, components such as central processing units (CPUs) and memory systems each employ a large quantity of transistors for logic circuits and memory devices.

As electronic devices become more complex in functionality, so does the need to include a greater number of transistors in such devices. But as electronic devices are required to be provided in increasingly smaller packages, such as in mobile devices for example, there is need to provide a greater number of transistors in a smaller IC chip. This increase in the number of transistors is achieved in part through continued efforts to miniaturize transistors in ICs (i.e., placing increasingly more transistors into the same amount of space). In particular, node sizes in ICs are being scaled down by a reduction in minimum metal line width in the ICs (e.g., 65 nanometers (nm), 45 nm, 28 nm, 20 nm, etc.). As a result, the gate lengths of planar transistors are also scalably reduced, thereby reducing the channel length of the transistors and interconnects. Reduced channel length in planar transistors has the benefit of increasing drive strength (i.e., increased drain current) and providing smaller parasitic capacitances resulting in reduced circuit delay. However, as channel length in planar transistors is reduced such that the channel length is of the same order of magnitude as the depletion layer widths, short channel effects (SCEs) can occur that degrade performance More specifically, SCEs in planar transistors cause increased current leakage, reduced threshold voltage, and/or threshold voltage roll-off (i.e., reduced threshold voltage at shorter gate lengths).

In this regard, to address the need to scale down channel lengths in transistors while avoiding or mitigating the effect of SCEs, alternative transistor designs to planar transistors have been developed. For example, a FinFET has been developed that provides a conductive channel wrapped by a thin silicon “Fin,” which forms a gate of a device. In this regard, FIG. 1A illustrates an exemplary FinFET 100. The FinFET 100 includes a body 102 (e.g., an oxide layer). The FinFET 100 includes a source 104 and a drain 106 interconnected by a Fin 108 that includes a conduction channel 110 (“channel 110”), as shown in FIG. 1B. The Fin 108 is surrounded by a “wrap-around” metal gate 112 (“gate 112”) that provides a gate material adjacent to the Fin 108. As shown in FIG. 1B, an interfacial layer 114 and a dielectric material layer 116 are disposed around the channel 110 to insulate the gate 112 from the channel 110. The wrap-around structure of the gate 112 around the channel 110 provides better electrostatic control over the channel 110 over planar transistors, thus reducing leakage current and overcoming other SCEs. The effective channel width of the Fin 108 in FIG. 1A is WFin HFin*2, which is the total measure of the gate's 112 electrostatic control over the channel 110, Further, providing a larger cross-sectional area of the Fin 108 allows a greater drive current, thereby increasing drive strength and providing an effective reduced channel length as compared to planar transistors.

Even with FinFETs, there still may be a need to improve transistor performance. For example, to reduce FinFET device delay, the width of the Fin can be reduced. However, reduction of the width of the Fin reduces the effective channel width and may not result in the desired frequency performance, such as for radio-frequency (RF) applications. Further, as FinFETs are miniaturized, it may be difficult to retain the current metal pitch to Fin pitch ratios while still meeting other process and design criteria, such as cost effective Fin and metal patterning processes, metal width, metal space, and Fin height or the like. Accordingly, there needs to be a new way to design smaller FinFETs that provide effective electrostatic control over a channel.

### SUMMARY OF THE DISCLOSURE

Aspects of the present disclosure involve nanowire metal-oxide semiconductor (MOS) Field-Effect Transistors (FETs) (MOSFETs) employing a nanowire channel structure employing recessed conductive structures for conductively coupling nanowire structures. The use of a nanowire channel structure in a MOSFET provides for an effective smaller channel length as compared to planar transistors to increase drive strength with strong electrostatic gate control of the channel to reduce leakage current. To increase the effective channel width of the nanowire channel structure for increased drive strength (i.e., drive current), multiple nanowire structures can be provided and vertically stacked in a nanowire channel structure in a nanowire MOSFET to increase channel current density for a given nanowire channel structure height. Scaling down the vertical space between adjacent, vertically stacked nanowire structures in a nanowire channel structure also reduces parasitic capacitances, thereby reducing delay of the nanowire MOSFET and increasing frequency performance as a result. However, there is a minimum distance required between adjacent nanowire structures due to fabrication limitations to allow gate material to be disposed to surround the adjacent nanowire structures to provide sufficient electrostatic control of the channel. Thus, scaling down the vertical space between adjacent, vertically stacked nanowire structures in a nanowire channel structure can decrease the amount of gate material provided in the nanowire channel structure for a given height, thereby reducing electrostatic control of the channel and increasing gate resistance, which increases delay of the nanowire MOSFET.

In this regard, to provide for multiple vertically stacked nanowire structures in a nanowire channel structure to increase drive strength, but with a reduced gate resistance and a relaxation of the distance between adjacent nanowire structures to ease the gate material filling process, nanowire MOSFETs employing a nanowire channel structure employing conductive structures conductively coupled to the nanowire structures are provided. The conductive structures are disposed in an area between adjacent nanowire structures in the nanowire channel structure that would otherwise be left void and subsequently filled in with gate material. The conductive structures provide an effective conductive “bridge” between adjacent nanowire structures to conductively couple the nanowire structures together in the nanowire channel structure. Providing the conductive structures in the nanowire channel structure increases the average cross-sectional area of the nanowire structures, as compared to a similar nanowire channel structure not employing the conductive structures, thus increasing the effective channel width and drive strength (i.e., drive current) for a given channel structure height. The precision of a gate material filling process is also eased, because the gate material does not have to be disposed in the areas between adjacent nanowire structures occupied by the conductive structures. Thus, the nanowire structures may be located closer to each other to provide a greater effective channel width and drive strength without having to increase the height of the nanowire channel structure. The width of the conductive structures can also be recessed with regard to the width of the nanowire structures in the nanowire channel structure to allow for a thicker metal gate to lower gate resistance, while still providing excellent electrostatic gate control of the channel.

Note that the nanowire structures provided in the nanowire channel structures in MOSFETs disclosed herein can be provided in any form of nanowire. For example, the nanowire structures can be provided as nanowires, nanoslabs, and/or nanosheets. A nanowire has a two-dimensional (2D) cross-section that has the same horizontal (i.e., X) and vertical (i.e., Y) dimensions. A nanoslab is a nanowire that has a 2D cross-section that has different X and Y dimensions, with the Y dimension typically being larger than the X dimension. A nanosheet is a nanowire that has a 2D cross-section with the X dimension typically being much larger than the Y dimension.

In this regard, in one exemplary aspect, a nanowire MOSFET is provided. The nanowire MOSFET comprises a substrate. The nanowire MOSFET also comprises a channel body disposed adjacent to the substrate. The channel body comprises a nanowire channel structure. The nanowire channel structure comprises a plurality of nanowire structures arranged in a vertically stacked arrangement about the substrate, each of the plurality of nanowire structures having a width about a width axis. The nanowire channel structure also comprises a plurality of conductive structures each disposed between and conductively coupling adjacent nanowire structures among the plurality of nanowire structures. Each of the plurality of conductive structures is recessed from the adjacent nanowire structures about the width axis of the adjacent nanowire structures.

In another exemplary aspect, a nanowire MOSFET is provided. The nanowire MOSFET comprises a means for providing a substrate. The nanowire MOSFET also comprises a means for providing a nanowire channel disposed about the means for providing a substrate. The means for providing the nanowire channel comprises a means for providing a plurality of conductive channel paths arranged in a vertically stacked arrangement about the means for providing the substrate, each of the plurality of conductive channel paths having a width about a width axis. The nanowire channel also comprises a means adjacent to and recessed about the width axis from each of the means for providing the plurality of conductive channel paths for conductively coupling the means for providing the plurality of conductive channel paths.

In another exemplary aspect, a method of fabricating a nanowire MOSFET is provided. The method comprises forming a semiconductor die for a MOSFET comprising forming a substrate, and forming a nanowire channel structure on the substrate. Forming the nanowire channel structure on the substrate comprises forming a plurality of alternating material layers comprising a plurality of first material layers comprising a plurality of nanowire structures each of a first width about a width axis, and a plurality of second material layers comprising a plurality of conductive structures each of the first width and interdisposed between and adjacent to the plurality of first material layers. The method also comprises removing a plurality of regions in the plurality of second material layers along the width axis to recess the plurality of second material layers about the width axis from the plurality of first material layers, to recess the plurality of conductive structures from the plurality of nanowires structures

### BRIEF DESCRIPTION OF THE FIGURES

FIG. 1A illustrates an exemplary Fin Field-Effect Transistor (FET) (FinFET);

FIG. 1B is a close-up, cross-sectional view of a Fin in the FinFET in FIG. 1A taken along line A-A;

FIG. 2A illustrates an exemplary nanowire metal-oxide semiconductor (MOS) FET (MOSFET);

FIG. 2B illustrates a close-up, cross-sectional view of a channel body in the nanowire MOSFET in FIG. 2A;

FIGS. 3A-3C are exemplary MOSFET channel structures to illustrate differences in drive strength between a FinFET channel structure and nanowire channel structures for a given channel structure height;

FIG. 4 is an exemplary nanowire MOSFET employing a nanowire channel structure employing recessed conductive structures for conductively coupling nanowire structures, to increase a cross-sectional area of a channel for increased channel current density with increased drive strength and reduced gate resistance, while still providing excellent electrostatic gate control of the channel;

FIG. 5 illustrates another exemplary nanowire channel structure that can be employed in a nanowire MOSFET, wherein the nanowire channel structure employs recessed conductive structures between adjacent nanowire structures;

FIG. 6 is a flowchart illustrating an exemplary process of fabrication of the nanowire MOSFET in FIG. 5;

FIGS. 7A-1 and 7A-2 are side perspective and front, cross-sectional diagrams, respectively, of a process stage of the exemplary fabrication process in FIG. 6 of forming semiconductor Fin structures (“Fin structures”) above a shallow trench isolation substrate (“substrate”) for fabricating an exemplary nanowire MOSFET employing a nanowire channel structure employing recessed conductive structures for conductively coupling nanowire structures;

FIGS. 7B-1 and 7B-2 are side perspective and front, cross-sectional diagrams, respectively, of another process stage of the exemplary fabrication process in FIG. 6 of forming an isolation layer over a bottom portion of the Fin structures, above the substrate, for fabricating an exemplary nanowire MOSFET employing a nanowire channel structure employing recessed conductive structures for conductively coupling nanowire structures;

FIGS. 7C-1 and 7C-2 are side perspective and front, cross-sectional diagrams, respectively, of another process stage of the exemplary fabrication process in FIG. 6 of disposing an oxide layer above the Fin structures, and a poly mask/dummy gate above the substrate and above the Fin structures for later formation of spacer layers, a drain, and a source for fabricating an exemplary nanowire MOSFET employing a nanowire channel structure employing recessed conductive structures for conductively coupling nanowire structures;

FIGS. 7D-1 and 7D-2 are side perspective and front, cross-sectional diagrams, respectively, of another process stage of the exemplary fabrication process in FIG. 6 of disposing spacer layers on the substrate adjacent to a poly mask/dummy gate, and disposing a source and a drain on the substrate adjacent to the spacer layers, respectively, for fabricating an exemplary nanowire MOSFET employing a nanowire channel structure employing recessed conductive structures for conductively coupling nanowire structures;

FIGS. 7E-1 and 7E-2 are side perspective and front, cross-sectional diagrams, respectively, of another process stage of the exemplary fabrication process in FIG. 6 of removing a poly mask/dummy gate and exposing the Fin structures for fabricating an exemplary nanowire MOSFET employing a nanowire channel structure employing recessed conductive structures for conductively coupling nanowire structures;

FIG. 8 is a block diagram of an exemplary processor-based system that can include nanowire MOSFETs employing a nanowire channel structure employing recessed conductive structures for conductively coupling nanowire structures, and according to the exemplary aspects disclosed herein; and

FIG. 9 is a block diagram of an exemplary wireless communications device that includes radio-frequency (RF) components which include nanowire MOSFETs employing a nanowire channel structure employing recessed conductive structures for conductively coupling nanowire structures, and according to the exemplary aspects disclosed herein.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects of the present disclosure involve nanowire metal-oxide semiconductor (MOS) Field-Effect Transistors (FETs) (MOSFETs) employing a nanowire channel structure employing recessed conductive structures for conductively coupling nanowire structures. The use of a nanowire channel structure in a MOSFET provides for an effective smaller channel length as compared to planar transistors to increase drive strength with strong electrostatic gate control of the channel to reduce leakage current. To increase the effective channel width of the nanowire channel structure for increased drive strength (i.e., drive current), multiple nanowire structures can be provided and vertically stacked in a nanowire channel structure in a nanowire MOSFET to increase channel current density for a given nanowire channel structure height. Scaling down the vertical space between adjacent, vertically stacked nanowire structures in a nanowire channel structure also reduces parasitic capacitances, thereby reducing delay of the nanowire MOSFET and increasing frequency performance as a result. However, there is a minimum distance required between adjacent nanowire structures due to fabrication limitations to allow gate material to be disposed to surround the adjacent nanowire structures to provide sufficient electrostatic control of the channel. Thus, scaling down the vertical space between adjacent, vertically stacked nanowire structures in a nanowire channel structure can decrease the amount of gate material provided in the nanowire channel structure for a given height, thereby reducing electrostatic control of the channel and increasing gate resistance, which increases delay of the nanowire MOSFET.

In this regard, to provide for multiple vertically stacked nanowire structures in a nanowire channel structure to increase drive strength, but with a reduced gate resistance and a relaxation of the distance between adjacent nanowire structures to ease the gate material filling process, nanowire MOSFETs employing a nanowire channel structure employing conductive structures conductively coupled to the nanowire structures are provided. The conductive structures are disposed in an area between adjacent nanowire structures in the nanowire channel structure that would otherwise be left void and subsequently filled in with gate material. The conductive structures provide an effective conductive “bridge” between adjacent nanowire structures to conductively couple the nanowire structures together in the nanowire channel structure. Providing the conductive structures in the nanowire channel structure increases the average cross-sectional area of the nanowire structures, as compared to a similar nanowire channel structure not employing the conductive structures, thus increasing the effective channel width and drive strength (i.e., drive current) for a given channel structure height. The precision of a gate material filling process is also eased, because the gate material does not have to be disposed in the areas between adjacent nanowire structures occupied by the conductive structures. Thus, the nanowire structures may be located closer to each other to provide a greater effective channel width and drive strength without having to increase the height of the nanowire channel structure. The width of the conductive structures can also be recessed with regard to the width of the nanowire structures in the nanowire channel structure to allow for a thicker metal gate to lower gate resistance, while still providing excellent electrostatic gate control of the channel.

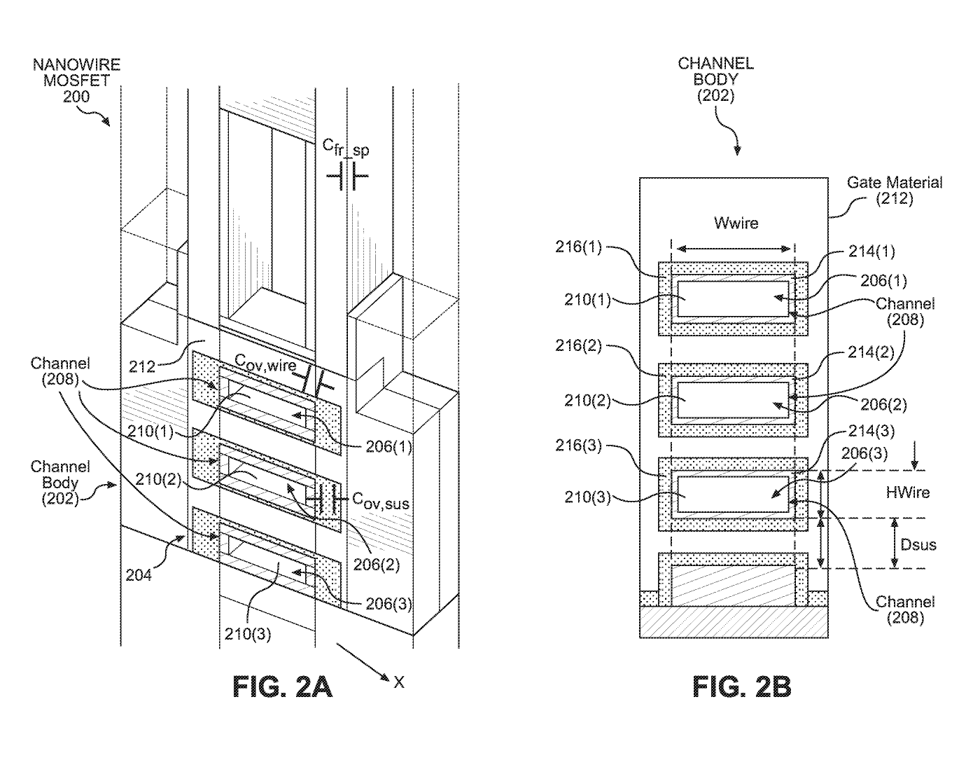

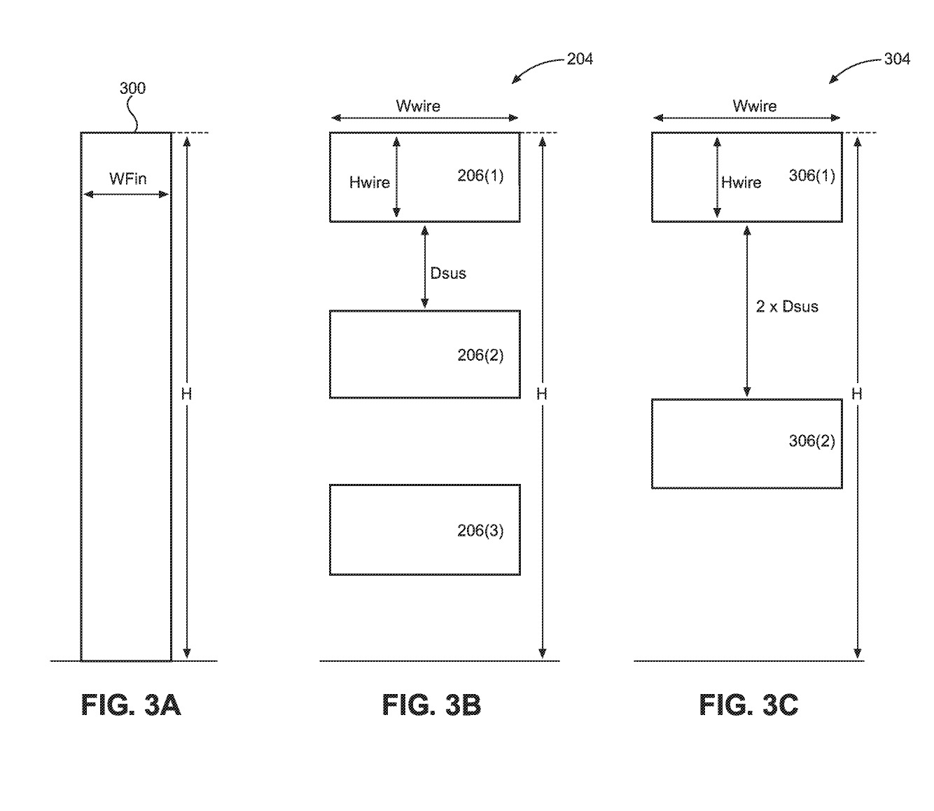

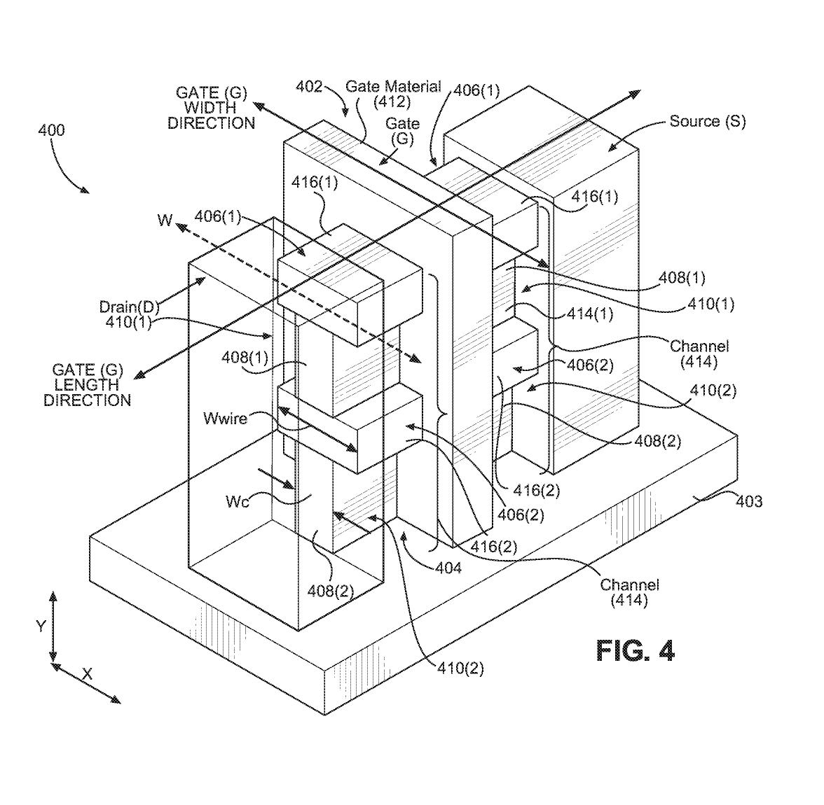

Before discussing examples of nanowire MOSFETs employing a nanowire channel structure employing recessed conductive structures for conductively coupling nanowire structures to form a channel starting at FIG. 4, FIGS. 2-3C are first described below to discuss examples of nanowire channels structures that do not include conductive structures for conductively coupled nanowire structures together.

FIG. 2A illustrates an exemplary nanowire MOSFET 200 that does not include a channel body having conductively coupled nanowire structures for discussion purposes. As shown in FIG. 2A, the nanowire MOSFET 200 includes a channel body 202 that includes a nanowire channel structure 204 that includes a plurality of nanowire structures 206(1)-206(3) that form a channel 208. The plurality of nanowire structures 206(1)-206(3) are arranged in a vertically stacked arrangement to increase channel current density for a given channel body 202 height, and thus increase the effective channel width for increased drive strength (i.e., drive current). In this example, the nanowire structures 206(1)-206(3) are nanoslabs 210(1)-210(3) that are elongated in the horizontal (X-axis) direction. FIG. 2B illustrates a close-up, side view of the channel body 202 in the nanowire MOSFET 200 in FIG. 2A. As shown in FIGS. 2A and 2B, a gate material 212 in the form of a metal material completely surrounds the nanowire structures 206(1)-206(3). Before the gate material 212 is disposed, an interfacial layer 214(1)-214(3) is disposed around the respective nanowire structures 206(1)-206(3) followed by a high-K dielectric material layer 216(1)-216(3) to insulate the gate material 212 from the nanowire structures 206(1)-206(3). In this manner, applying a voltage to the gate material 212 controls an electric field in the nanowire structures 206(1)-206(3) to cause current to flow through the nanowire structures 206(1)-206(3) during an active mode.

FIG. 2B illustrates the channel body 202 of the nanowire MOSFET 200 in FIG. 2A in more detail. The length of each of the nanowire structures 206(1)-206(3) is of a height of Hwire in this example. The cross-sectional area of the nanowire structures 206(1)-206(3) of the channel 208 allows a greater drive current, thereby increasing drive strength of the nanowire MOSFET 200. Adjacent nanowire structures 206(1)-206(3) are separated a distance Dsus from each other as shown in FIG. 2B. This distance Dsus is provided to allow the gate material 212 to be disposed completely around and between the adjacent nanowire structures 206(1)-206(3) so that the gate material 212 can have greater electrostatic control of the channel 208 formed by the nanowire structures 206(1)-206(3) of the nanowire MOSFET 200. The distance Dsus may be fourteen (14) nanometers (nm) as an example in a conventional nanowire channel structure, such as the nanowire channel structure 204. It may be desired to minimize the distance Dsus between the adjacent nanowire structures 206(1)-206(3) to minimize the parasitic capacitance formed as a result of the adjacent nanowire structures 206(1)-206(3). Reducing parasitic capacitance can reduce the delay of the nanowire MOSFET 200 and increase its frequency performance, which may be important for example, if the nanowire MOSFET 200 is used in radio-frequency (RF) applications. It may be desired to reduce the distance Dsus to reduce parasitic capacitance in the channel body 202, as well as to have more area for including additional nanowire structures 206(1)-206(3) to provide increased drive strength of the nanowire MOSFET 200 for a given channel body 202 size. However, fabrication limitations may prevent the ability to insert the gate material 212 between adjacent nanowire structures 206(1)-206(3) with a smaller distance Dsus between the adjacent nanowire structures 206(1)-206(3). Thus, the distance Dsus may be designed based on fabrication limitations on the minimum space needed between adjacent nanowire structures 206(1)-206(3) to be able to dispose the gate material 212 between adjacent nanowire structures 206(1)-206(3).

To increase the effective channel width of the nanowire MOSFET 200 in FIGS. 2A and 2B for increased drive strength (i.e., drive current), the multiple nanowire structures 206(1)-206(3) are provided. Providing multiple nanowire structures 206(1)-206(3) can increase channel current density over, for example, a Fin of a FinFET for a given nanowire channel structure 204 height. For example, as shown in FIGS. 3A-3C, for a nanowire channel structure height of H, the nanowire channel structure 204 shown in FIG. 3B has a larger effective channel width than a Fin 300 for a FinFET in FIG. 3A. For example, if the height H is 42 nm, height Hwire is 7 nm, Wwire is 15 nm, and distance Dsus is 7 nm, the effective channel width of the Fin 300 would be 91 nm (i.e., (H*2)+Dsus). FIG. 3B illustrates the nanowire channel structure 204 of the nanowire MOSFET 200 in FIG. 2A. As shown in FIG. 3B, the effective channel width of the nanowire channel structure 204 in FIG. 3B would be 132 nm (i.e., (Wwire*6)+(Hwire*6)). However, scaling down the vertical distance Dsus between the adjacent, vertically stacked nanowire structures 206(1)-206(3) in the nanowire channel structure 204 also reduces parasitic capacitance, and may also cause fabrication issues due to fabrication limitations to allow the gate material 212 to be disposed between the nanowire structures 206(1)-206(3) to provide sufficient electrostatic control. Thus, scaling down the vertical distance Dsus between adjacent, vertically stacked nanowire structures 206(1)-206(3) in the nanowire channel structure 204 can decrease the amount of gate material 212 provided in the nanowire channel structure 204 for a given height H, thereby increasing gate resistance and increasing delay of the nanowire MOSFET 200 in FIG. 2A.

As shown in FIG. 3C, a nanowire channel structure 304 could be provided that has fewer nanowire structures 306(1), 306(2) than the nanowire channel structure 204 in FIG. 3B for the given height H to allow a gate material to more easily be disposed around the nanowire structures 306(1), 306(2) for channel control. In this example the nanowire channel structure 304 in FIG. 3C has two (2) nanowire structures 306(1), 306(2) each of height Hwire, whereas the nanowire channel structure 204 in FIG. 3B has three (3) nanowire structures 206(1), 206(2), 206(3) each of height Hwire. Thus, the distance Dsus between adjacent nanowire structures 206(1), 206(2) in FIG. 3B is less than the distance 2*Dsus in this example between adjacent nanowire structures 306(1), 306(2) in FIG. 3C. However, the effective channel width of the nanowire channel structure 304 in FIG. 3C is less than the effective channel width of the nanowire channel structure 204 in FIG. 3B, thereby reducing drive strength and increasing parasitic capacitance. In this example of the nanowire channel structure 304 in FIG. 3C, the effective channel width is 88 nm (i.e., (Wwire*4)+(Hwire*4)), as opposed to 132 nm for the nanowire channel structure 204 in this example. The effective channel width being 88 nm for the nanowire channel structure 304 in FIG. 3C is worse that the effective channel width of both the Fin 300 in FIG. 3A and the nanowire channel structure 204 in FIG. 3B.

In this regard, to provide an increased effective channel width of a nanowire channel structure similar to the nanowire channel structure 204 in FIG. 3B for increased drive strength, but also to provide a greater separation distance between the adjacent nanowire structures 306(1), 306(2) in FIG. 3C to allow gate material to more easily be disposed around the nanowire structures 306(1), 306(2) for increased channel control, an exemplary nanowire MOSFET 400 is provided in FIG. 4. As will be discussed in more detail below, FIG. 4 illustrates the nanowire MOSFET 400 that includes a channel body 402 on a substrate 403 with a nanowire channel structure 404 that includes multiple vertically stacked nanowire structures 406(1)-406(2) to increase drive strength. To provide for an increased drive strength with a reduced gate resistance and relaxation of the distance between adjacent nanowire structures 406(1)-406(2) to ease the gate material filling process, the nanowire channel structure 404 also includes recessed conductive structures 408(1), 408(2) disposed in areas 410(1), 410(2) left void between the adjacent nanowire structures 406(1), 406(2) in the nanowire channel structure 404 to provide an effective conductive “bridge” between the adjacent nanowire structures 406(1), 406(2). Providing the conductive structures 408(1), 408(2) in the nanowire channel structure 404 increases the cross-sectional area of the nanowire channel structure 404, as compared to a similar nanowire channel structure not employing the conductive structures 408(1), 408(2) (e.g., see FIG. 3B), thus increasing the effective channel width and drive strength (i.e., drive current) for a given channel structure height. The precision of filling the areas 410(1), 410(2) between the adjacent nanowire structures 406(1), 406(2) with a gate material 412 that would otherwise be left void is also eased, because the gate material 412 does not have to be disposed in the areas 410(1), 410(2) between the nanowire structures 406(1), 406(2) occupied by the conductive structures 408(1), 408(2). The gate material 412 may be chosen from a low resistance material to provide a low resistance gate (G) for the nanowire MOSFET 400.

With continuing reference to FIG. 4, the nanowire MOSFET 400 employs the channel body 402 disposed between a drain (D) and a source (S). The channel body 402 includes the nanowire channel structure 404 that includes a plurality of nanowire structures 406(1), 406(2) that form a channel 414 between the drain (D) and the source (S). In this example, the nanowire structures 406(1), 406(2) are nanoslabs 416(1), 416(2) that are elongated in the horizontal (X-axis) direction. For example, the nanoslabs 416(1), 416(2) may be formed from a Silicon (Si), a Si Germanium (Ge) (SiGe), Ge, or any type of III-V material as non-limiting examples. The gate material 412 in the form of a metal material in this example completely surrounds the nanowire channel structure 404 to form a gate (G) node.

With continuing reference to FIG. 4, the nanowire channel structure 404 in the nanowire MOSFET 400 employs the conductive structures 408(1), 408(2) conductively coupling the multiple, vertically stacked nanowire structures 406(1), 406(2). The conductive structures 408(1), 408(2) may be made of Si, SiGe, Ge, or any type of III-V material as non-limiting examples. The conductive structures 408(1), 408(2) are disposed in the areas 410(1), 410(2) between the adjacent nanowire structures 406(1), 406(2) in the nanowire channel structure 404 that would otherwise be left void and subsequently filled in with the gate material 412. The conductive structures 408(1), 408(2) provide an effective conductive “bridge” between the adjacent nanowire structures 406(1), 406(2) to conductively couple the nanowire structures 406(1), 406(2) together in the nanowire channel structure 404. Providing the conductive structures 408(1), 408(2) in the nanowire channel structure 404 increases the average cross-sectional area of the nanowire channel structure 404, as compared to a similar nanowire channel structure not employing the conductive structures 408(1), 408(2), thus increasing the effective channel width and drive strength (i.e., drive current) for a given channel structure height. The precision of the gate material 412 filling process is also eased, because the gate material 412 does not have to be disposed in the areas 410(1), 410(2) between the nanowire structures 406(1), 406(2) occupied by the conductive structures 408(1), 408(2).

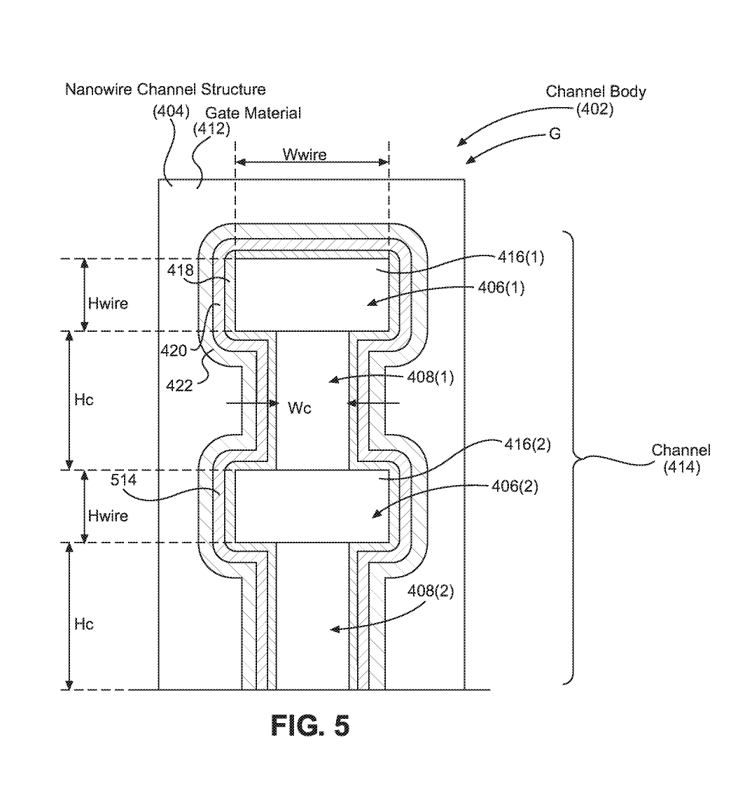

With continuing reference to FIG. 4, the width Wc of the conductive structures 408(1), 408(2) in this example is recessed from the nanowire structures 406(1), 406(2) in the nanowire channel structure 404 about a width axis W of the nanowire structures 406(1), 406(2). For example, the conductive structures 408(1), 408(2) may be recessed between one (1) and thirty (30) nanometers (nm) from respective adjacent nanowire structures 406(1), 406(2), about the width axis W of the respective adjacent nanowire structures 406(1), 406(2). This allows for providing a thicker gate material 412 to lower the gate (G) resistance in the nanowire MOSFET 400, while still providing excellent electrostatic gate control of the channel 414 provided by the nanowire channel structure 404. This is also shown in more detail in FIG. 5, which illustrates the channel body 402 of the nanowire MOSFET 400 in FIG. 4.

As shown in FIG. 5, the effective channel width of the nanowire channel structure 404 is (4*Wwire)+(4*Hwire)+(4*height Hc)−(3*width Wc), where ‘Wwire’ is the width of the nanowire structures 406(1), 406(2), ‘Hwire’ is the height of the nanowire structures 406(1), 406(2), ‘Hc’ is the height of the conductive structures 408(1), 408(2), and ‘Wc’ is the width of the conductive structures 408(1), 408(2). For example, if Wwire is 15 nm, Hwire is 7 nm, Hc is 14 nm, and Wc is 7 nm, the effective channel width of the nanowire channel structure 404 would be 123 nm. The effective channel width of the nanowire channel structure 404 in FIG. 5 may be less than the effective channel width of a similar nanowire channel structure employing additional nanowire structures for a given nanowire channel structure height, such as the nanowire channel structure 204 in FIG. 3B. However, the effective channel width of the nanowire channel structure 404 in FIG. 5 may be greater than the effective channel width of a nanowire channel structure having the same number of nanowire channel structures without employing conductive structures conductively coupling the nanowire structures, such as the nanowire channel structure 304 in FIG. 3C. However, in the nanowire channel structure 404 in FIG. 5, the precision of the gate material 412 filling process is also eased, because as previously discussed, the gate material 412 does not have to be disposed in the areas 410(1), 410(2) between adjacent nanowire structures 406(1), 406(2) occupied by the conductive structures 408(1), 408(2), as shown in FIG. 5. The width We of the conductive structures 408(1), 408(2) is recessed with regard to the width Wwire of the nanowire structures 406(1), 406(2) in the nanowire channel structure 404 to allow for a thicker gate material 412 to lower the gate (G) resistance, while still providing excellent electrostatic gate control of the channel 414.

With continuing reference to FIG. 5, before the gate material 412 is disposed around the nanowire structures 406(1), 406(2), additional layers may first be disposed around the nanowire structures 406(1), 406(2) and the conductive structures 408(1), 408(2) to insulate the gate material 412 from the nanowire structures 406(1), 406(2) and the conductive structures 408(1), 408(2). For example, an interfacial layer 418 may be disposed around the nanowire structures 406(1), 406(2) and the conductive structures 408(1), 408(2), followed by a dielectric material layer 420. A gate work function material 422 may be disposed around the dielectric material layer 420 to tune the nanowire MOSFET 400 for either operating as a N-type semiconductor material MOS (NMOS) or P-type semiconductor material MOS (CMOS). In this manner, applying a voltage to the gate (G) formed by the gate material 412 that exceeds a threshold voltage of the nanowire MOSFET 400 controls an electric field in the nanowire channel structure 404 to cause current to flow through the nanowire structures 406(1), 406(2) and the conductive structures 408(1), 408(2) during an activated, or turned-on mode.

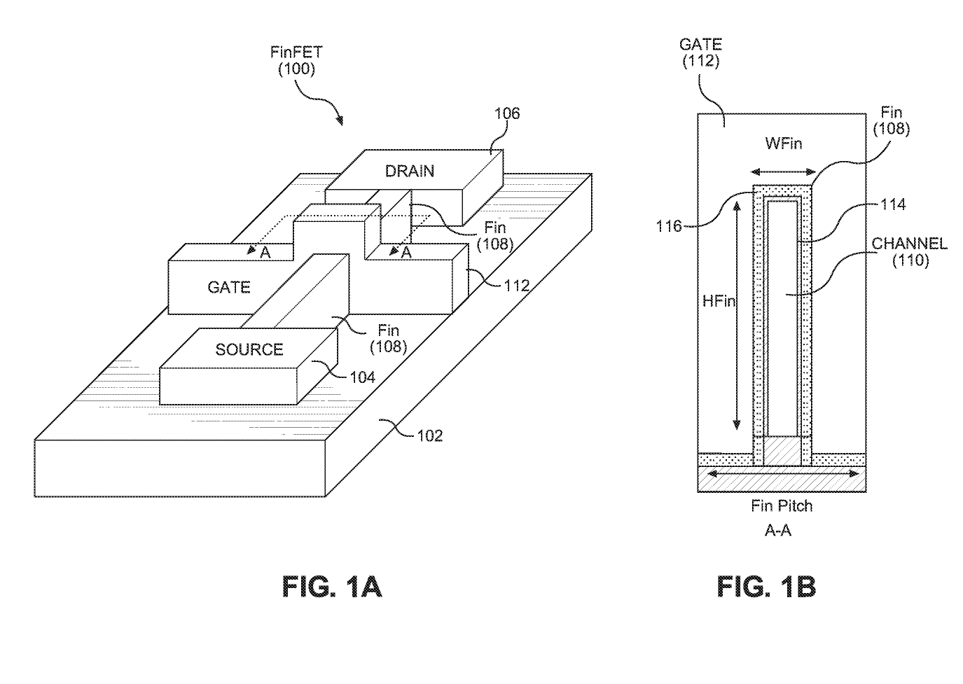

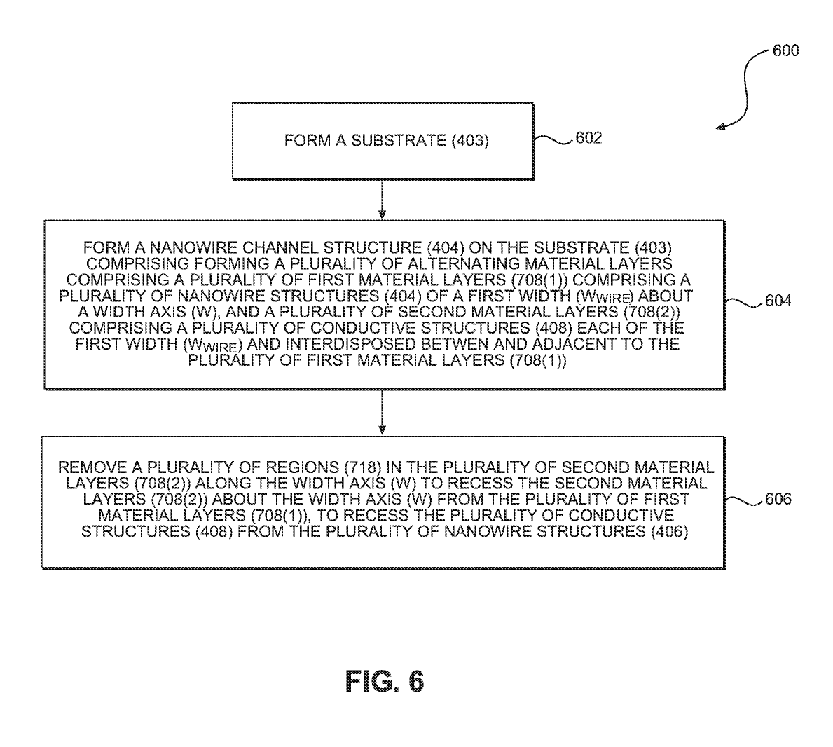

FIG. 6 is a flowchart that illustrates an exemplary process 600 of fabricating the nanowire MOSFET 400 in FIG. 4. FIGS. 7A-1-7E-2 illustrate exemplary process stages 700(1)-700(5) in the fabrication of the nanowire MOSFET 400 in FIG. 4. The process 600 in FIG. 6 will be described in conjunction with the process stages 700(1)-700(5) in FIGS. 7A-1-7E-2.

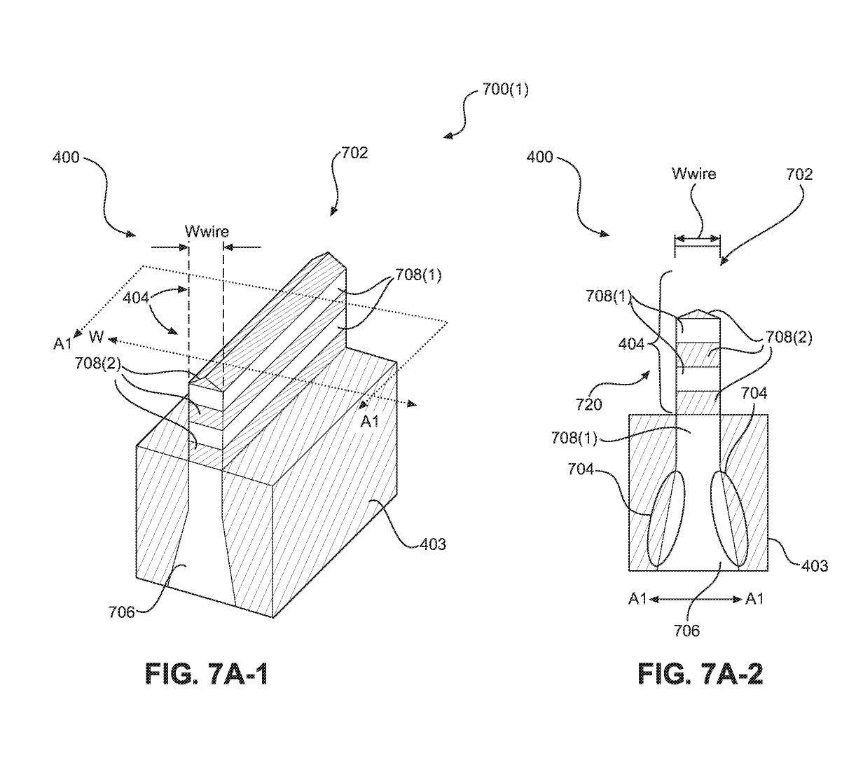

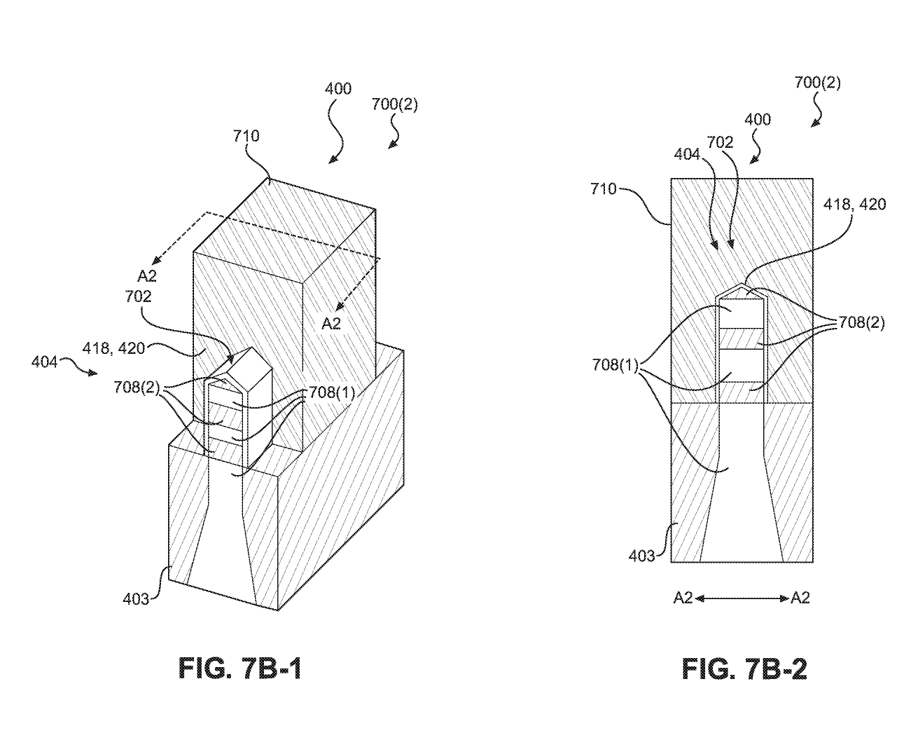

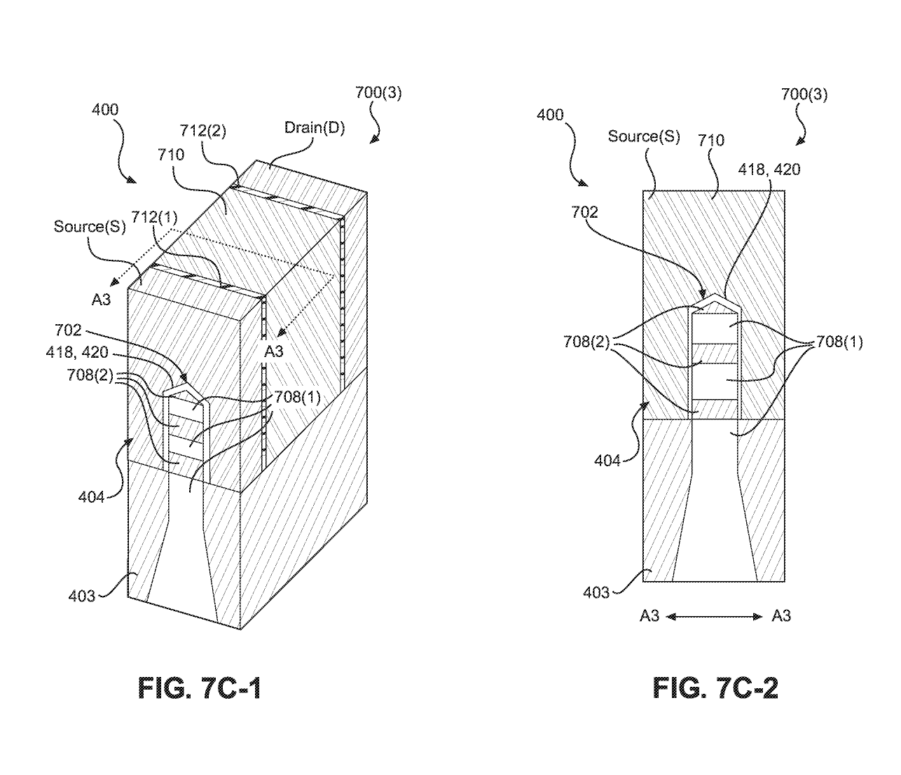

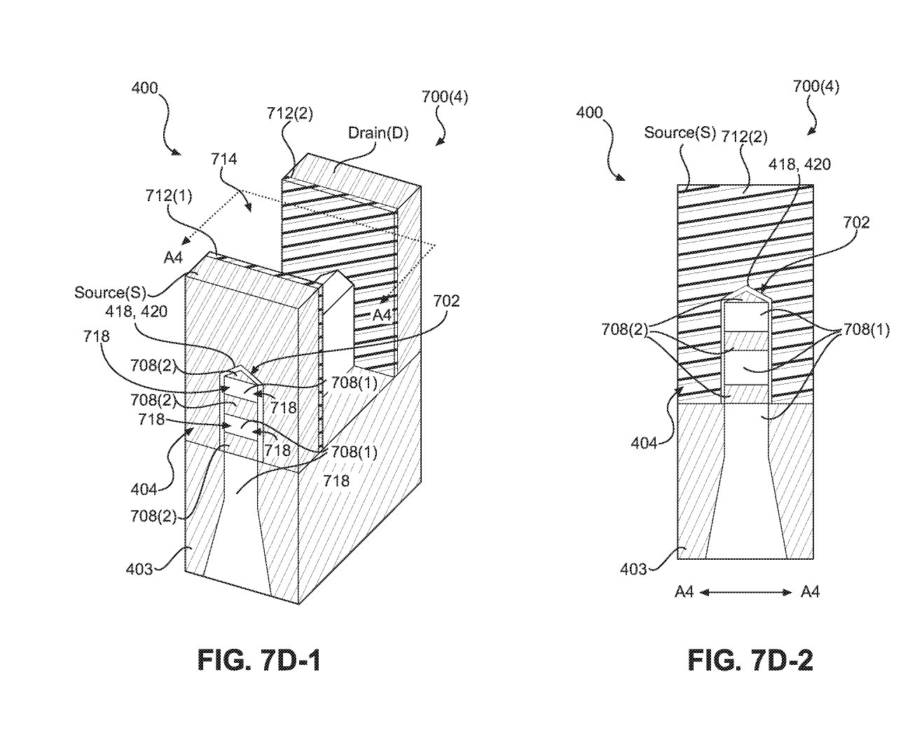

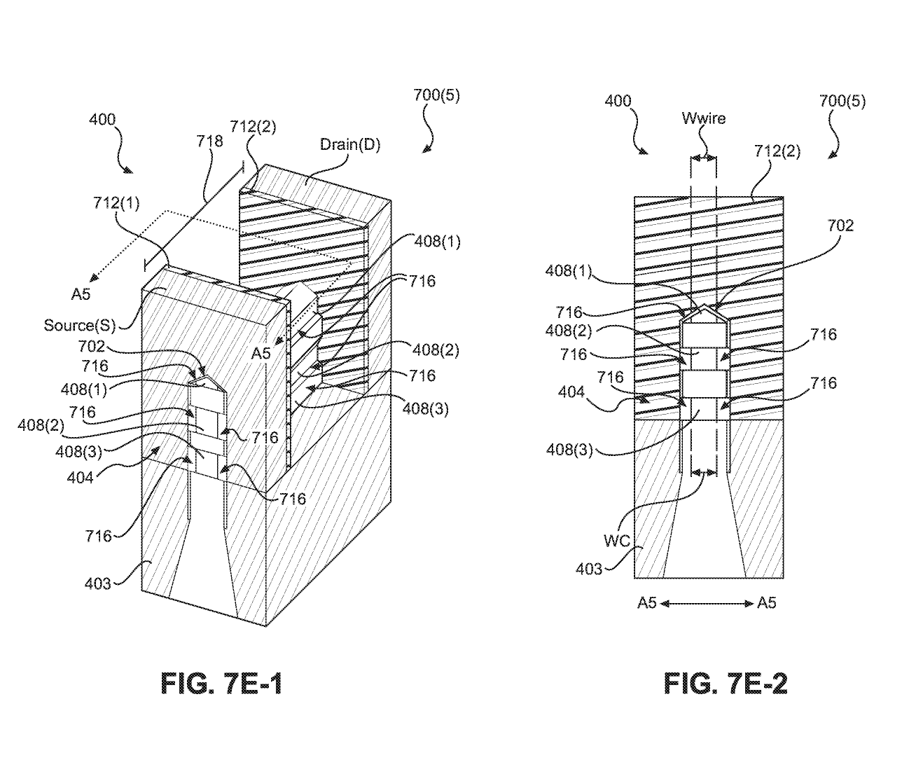

FIGS. 7A-1 and 7A-2 are side perspective and front, cross-sectional diagrams, respectively, of a process stage 700(1) of fabricating a nanowire MOSFET 400 in FIG. 4. In this regard, the nanowire MOSFET 400 is provided comprising a Fin structure 702 comprising the nanowire channel structure 404 of a desired width Wwire and of a desired height (e.g., 100 nm) that may be formed using a self-aligned quadruple patterning process, for example. A substrate 403 is formed and is recessed down to expose the nanowire channel structure 404 (block 602 in FIG. 6). The nanowire channel structure 404 is formed from an increased taper portion 704 near a bottom section 706, as shown in FIG. 7A-2 due to fabrication limitations that prevent etching a minimally tapered semiconductor structure, followed by deposing of a heterogeneous material layer structure comprising alternating first material layers 708(1) and second material layers 708(2) (block 604 in FIG. 6). The second material layers 708(2) are interdisposed between the first material layers 708(1). The first material layers 708(1) and second material layers 708(2) have different etch characteristics from each other in this example. For example, the first material layers 708(1) can be Silicon (Si) for example, and the second material layers 708(2) can be Silicon Germanium (SiGe) for example. As will be discussed in more detail below, portions of the second material layers 708(2) are removed (e.g., etched) to form the recessed conductive structures 408 (e.g., see the conductive structures 408(1), 408(2) in FIG. 4) conductively coupled to adjacent nanowire structures 406 formed from the first material layers 708(1).

FIGS. 7B-1 and 7B-2 are side perspective and front, cross-sectional diagrams, respectively, of a next process stage 700(2) of fabricating the nanowire MOSFET 400 in FIG. 4. The process stage 700(2) includes disposing the interfacial layer 418 and the dielectric material layer 420 around the exposed portions of the nanowire channel structure 404 as shown in FIG. 7B-2 and as previously discussed in FIG. 5. The dielectric material layer 420 is disposed around the exposed portions of the nanowire channel structure 404 for isolation of the nanowire channel structure 404. A poly mask/dummy gate 710 is disposed around the nanowire channel structure 404 without removing the first material layers 708(1) or the second material layers 708(2) from the nanowire channel structure 404 for later formation of spacer layers, a source (S), and a drain (D).

FIGS. 7C-1 and 7C-2 are side perspective and front, cross-sectional diagrams, respectively, of a next process stage 700(3) of fabricating the nanowire MOSFET 400 in FIG. 4. This process stage 700(3) includes adding spacer layers 712(1) and 712(2) on the substrate 403 adjacent to the poly mask/dummy gate 710 to provide isolation between the poly mask/dummy gate 710 and a source (S) and drain (D). The spacer layers 712(1) and 712(2) comprise a dielectric material. A source (S) and a drain (D) are then disposed on the substrate 403 adjacent to the spacer layers 712(1) and 712(2), respectively. The source (S) and the drain (D) may be disposed on the substrate 403 by growing conductive material over the nanowire channel structure 404 using an epitaxial growth process, as a non-limiting example.

FIGS. 7D-1 and 7D-2 illustrate side perspective and front, cross-sectional diagrams, respectively, of a next process stage 700(4) of fabricating the nanowire MOSFET 400 in FIG. 4. After forming the spacer layers 712(1), 712(2), the source (S), and the drain (D), the poly mask/dummy gate 710 is removed, thus exposing the nanowire channel structure 404 in a gate area 714 between the spacer layers 712(1), 712(2) to prepare a gate material to be disposed around the nanowire channel structure 404. The second material layers 708(2) have outer regions 718 that will be removed to form the recessed conductive structures 408(1), 408(2) as discussed below.

FIGS. 7E-1 and 7E-2 illustrate side perspective and front, cross-sectional diagrams, respectively, of a next process stage 700(5) of fabricating the nanowire MOSFET 400 in FIG. 4. In this process stage 700(5), trenches 716 are formed (e.g., etched) in the second material layers 708(2) to remove portions of the second material layers 708(2) in outer regions 718 (see FIGS. 7D-1 and 7D2) to form the recessed conductive structures 408(1)-408(2) (block 606 in FIG. 6). If etching is used to remove the portions of the second material layers 708(2) to form the recessed conductive structures 408(1)-408(2), the etching may be performed in a number of ways. For example, the etching can be performed as a time-based wet chemical etch, where the second material layers 708(2) are exposed to a wet chemical for a predetermined period of time according to a time necessary to etch a portion of the second material layers 708(2) to an etch stop. In particular, when the second material layers 708(2) are disposed/grown with a different surface orientation than a sidewall orientation material structure, exposing a layer of the second material layers 708(2) to the chemical etch causes an etching stop on a sidewall.

In other aspects, a nanowire MOSFET employing a nanowire channel structure employing recessed conductive structures for conductively coupling nanowire structures to form a channel can also include a means for providing a substrate. An example of a substrate is shown as the substrate 403 in FIGS. 4, 5, and 7A-1-7E-2. The nanowire MOSFET can also include a means for providing a nanowire channel disposed about the means for providing a substrate. Examples of a means for providing a nanowire channel is the nanowire channel structure 404 in FIGS. 4, 5, and 7A-1-7E-2. The means for providing the nanowire channel can comprise a means for providing a plurality of conductive channel paths arranged in a vertically stacked arrangement about the means for providing the substrate, each of the plurality of conductive channel paths having a width about a width axis. Examples of a means for providing a plurality of conductive channel paths is shown as the nanowire structures 406(1), 406(2) in FIGS. 4, 5, and 7A-1-7E-2. The means for providing a nanowire channel can also include a means adjacent to and recessed about the width axis from each of the means for providing the plurality of conductive channel paths for conductively coupling the means for providing the plurality of conductive channel paths. Examples of a means adjacent to and recessed about the width axis from each of the means for providing the plurality of conductive channel paths for conductively coupling the means for providing the plurality of conductive channel paths are shown as the conductive structures 408(1), 408(2) in FIGS. 4, 5, and 7A-1-7E-2.

Nanowire MOSFETs employing a nanowire channel structure employing recessed conductive structures for conductively coupling nanowire structures may be provided in or integrated into any processor-based device. Examples, without limitation, include a set top box, an entertainment unit, a navigation device, a communications device, a fixed location data unit, a mobile location data unit, a mobile phone, a cellular phone, a smart phone, a tablet, a phablet, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, and an automobile.

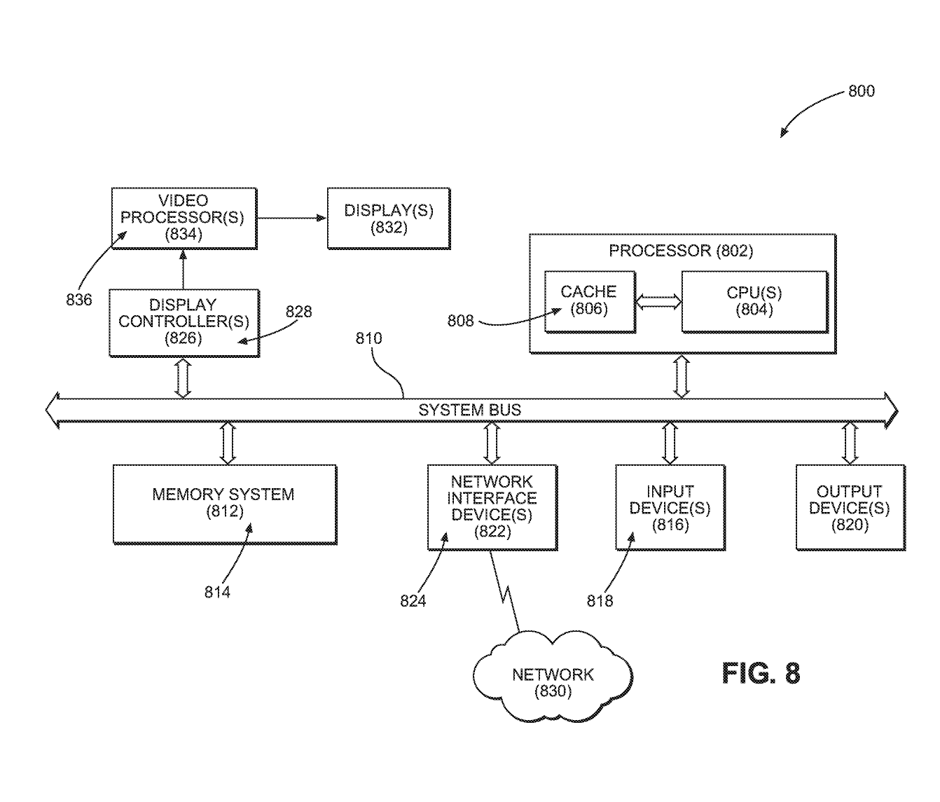

In this regard, FIG. 8 illustrates an example of a processor-based system 800 that can include nanowire MOSFETs employing a nanowire channel structure employing nanowire structures arranged in a vertically stacked arrangement with recessed conductive structures disposed between and conductively coupling adjacent nanowire structures. In this example, the processor-based system 800 includes a processor 802 that includes one or more CPUs 804. The processor 802 may have cache memory 806 coupled to the CPU(s) 804 for rapid access to temporarily stored data. The cache memory 806 may include nanowire MOSFETs 808 employing nanowire channel structures employing nanowire structures arranged in a vertically stacked arrangement with recessed conductive structures disposed between and conductively coupling adjacent nanowire structures. The processor 802 is coupled to a system bus 810 and can intercouple master and slave devices included in the processor-based system 800. As is well known, the processor 802 communicates with these other devices by exchanging address, control, and data information over the system bus 810. Although not illustrated in FIG. 8, multiple system buses 810 could be provided, wherein each system bus 810 constitutes a different fabric. For example, the processor 802 can communicate bus transaction requests to a memory system 812 as an example of a slave device. The memory system 812 may include memory structures or arrays that include nanowire MOSFETs 814 employing a nanowire channel structure employing nanowire structures arranged in a vertically stacked arrangement with recessed conductive structures disposed between and conductively coupling adjacent nanowire structures, as an example.

Other master and slave devices can be connected to the system bus 810. As illustrated in FIG. 8, these devices can include the memory system 812, one or more input devices 816, which can include nanowire MOSFETs 818. The nanowire MOSFETs 818 can employ a nanowire channel structure employing nanowire structures arranged in a vertically stacked arrangement with recessed conductive structures disposed between and conductively coupling adjacent nanowire structures as an example. The input device(s) 816 can include any type of input device, including but not limited to input keys, switches, voice processors, etc. These devices can also include one or more output devices 820, and one or more network interface devices 822, which can include nanowire MOSFETs 824 employing a nanowire channel structure employing nanowire structures arranged in a vertically stacked arrangement with recessed conductive structures disposed between and conductively coupling adjacent nanowire structures as an example. The output device(s) 820 can include any type of output device, including but not limited to audio, video, other visual indicators, etc. These devices can also include one or more display controllers 826, including nanowire MOSFETs 828 employing a nanowire channel structure employing nanowire structures arranged in a vertically stacked arrangement with recessed conductive structures disposed between and conductively coupling adjacent nanowire structures, as examples. The network interface device(s) 822 can be any devices configured to allow exchange of data to and from a network 830. The network 830 can be any type of network, including but not limited to a wired or wireless network, a private or public network, a local area network (LAN), a wireless local area network (WLAN), a wide area network (WAN), a BLUETOOTH™ network, and the Internet. The network interface device(s) 822 can be configured to support any type of communications protocol desired.

The processor 802 may also be configured to access the display controller(s) 826 over the system bus 810 to control information sent to one or more displays 832. The display controller(s) 826 sends information to the display(s) 832 to be displayed via one or more video processors 834, which process the information to be displayed into a format suitable for the display(s) 832. The video processor(s) 834 can include nanowire MOSFETs 836 employing a nanowire channel structure employing nanowire structures arranged in a vertically stacked arrangement with recessed conductive structures disposed between and conductively coupling adjacent nanowire structures, as an example. The display(s) 832 can include any type of display, including but not limited to a cathode ray tube (CRT), a liquid crystal display (LCD), a plasma display, etc.

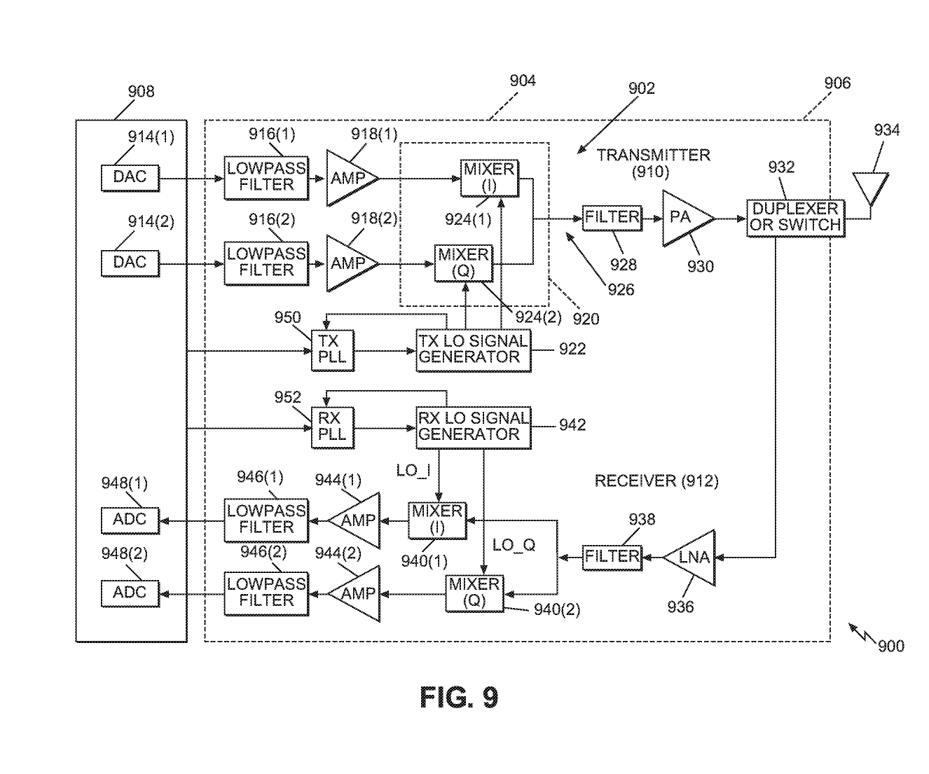

FIG. 9 illustrates an example of a wireless communications device 900 which can include RF components in which a nanowire channel structure employing nanowire structures arranged in a vertically stacked arrangement with recessed conductive structures disposed between and conductively coupling adjacent nanowire structures, including but not limited to the nanowire MOSFET 400 in FIGS. 4 and 5, may be included. In this regard, the wireless communications device 900, including a nanowire MOSFET 902 employing a nanowire channel structure employing nanowire structures and recessed conductive structures disposed between and conductively coupling adjacent nanowire structures, may be provided in an integrated circuit (IC) 906. The wireless communications device 900 may include or be provided in any of the above referenced devices, as examples. As shown in FIG. 9, the wireless communications device 900 includes a transceiver 904 and a data processor 908. The data processor 908 may include a memory (not shown) to store data and program codes. The transceiver 904 includes a transmitter 910 and a receiver 912 that support bi-directional communication. In general, the wireless communications device 900 may include any number of transmitters and/or receivers for any number of communication systems and frequency bands. All or a portion of the transceiver 904 may be implemented on one or more analog ICs, RF ICs (RFICs), mixed-signal ICs, etc.

A transmitter 910 or a receiver 912 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for a receiver 912. In the direct-conversion architecture, a signal is frequency converted between RF and baseband in one stage. The super-heterodyne and direct-conversion architectures may use different circuit blocks and/or have different requirements. In the wireless communications device 900 in FIG. 9, the transmitter 910 and the receiver 912 are implemented with the direct-conversion architecture.

In the transmit path, the data processor 908 processes data to be transmitted and provides I and Q analog output signals to the transmitter 910. In the exemplary wireless communications device 900, the data processor 908 includes digital-to-analog-converters (DACs) 914(1) and 914(2) for converting digital signals generated by the data processor 908 into the I and Q analog output signals, e.g., I and Q output currents, for further processing.

Within the transmitter 910, lowpass filters 916(1), 916(2) filter the I and Q analog output signals, respectively, to remove undesired images caused by the prior digital-to-analog conversion. Amplifiers (AMP) 918(1), 918(2) amplify the signals from the lowpass filters 916(1), 916(2), respectively, and provide I and Q baseband signals. An upconverter 920 upconverts the I and Q baseband signals with I and Q transmit (TX) local oscillator (LO) signals through mixers 924(1), 924(2) from a TX LO signal generator 922 to provide an upconverted signal 926. A filter 928 filters the upconverted signal 926 to remove undesired images caused by the frequency upconversion as well as noise in a receive frequency band. A power amplifier (PA) 930 amplifies the upconverted signal 926 from the filter 928 to obtain the desired output power level and provides a transmit RF signal. The transmit RF signal is routed through a duplexer or switch 932 and transmitted via an antenna 934.

In the receive path, the antenna 934 receives signals transmitted by base stations and provides a received RF signal, which is routed through the duplexer or switch 932 and provided to a low noise amplifier (LNA) 936. The duplexer or switch 932 is designed to operate with a specific RX-to-TX duplexer frequency separation, such that RX signals are isolated from TX signals. The received RF signal is amplified by the LNA 936 and filtered by a filter 938 to obtain a desired RF input signal. Downconversion mixers 940(1), 940(2) mix an output of the filter 938 with I and Q receive (RX) LO signals (i.e., LO_I and LO_Q) from an RX LO signal generator 942 to generate I and Q baseband signals. The I and Q baseband signals are amplified by amplifiers 944(1), 944(2) and further filtered by lowpass filters 946(1), 946(2) to obtain I and Q analog input signals, which are provided to the data processor 908. In this example, the data processor 908 includes analog-to-digital-converters (ADCs) 948(1), 948(2) for converting the analog input signals into digital signals to be further processed by the data processor 908.

In the wireless communications device 900 in FIG. 9, the TX LO signal generator 922 generates the I and Q TX LO signals used for frequency upconversion, while the RX LO signal generator 942 generates the I and Q RX LO signals used for frequency downconversion. Each LO signal is a periodic signal with a particular fundamental frequency. A transmit (TX) phase-locked loop (PLL) circuit 950 receives timing information from data processor 908 and generates a control signal used to adjust the frequency and/or phase of the TX LO signals from the TX LO signal generator 922. Similarly, a receive (RX) phase-locked loop (PLL) circuit 952 receives timing information from the data processor 908 and generates a control signal used to adjust the frequency and/or phase of the RX LO signals from the RX LO signal generator 942.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master devices and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A nanowire metal-oxide semiconductor (MOS) Field-Effect Transistor (FET) (MOSFET), comprising:
a substrate; and
a channel body disposed adjacent to the substrate, the channel body comprising:
a nanowire channel structure, comprising:
a plurality of nanowire structures arranged in a vertically stacked arrangement about the substrate, each of the plurality of nanowire structures having a width about a width axis; and
a plurality of conductive structures each disposed between and conductively coupling adjacent nanowire structures among the plurality of nanowire structures;
each of the plurality of conductive structures recessed from the adjacent nanowire structures about the width axis of the adjacent nanowire structures.

2. The nanowire MOSFET of claim 1, wherein each of the plurality of conductive structures is recessed between 1 and 30 nanometers (nm) from the adjacent nanowire structures about the width axis of the adjacent nanowire structures.

3. The nanowire MOSFET of claim 1, wherein the plurality of nanowire structures is comprised of a plurality of nanoslabs.

4. The nanowire MOSFET of claim 1, wherein the plurality of nanowire structures is comprised of a plurality of nanosheets.

5. The nanowire MOSFET of claim 1, wherein the plurality of nanowire structures is comprised of Silicon (Si), and the plurality of conductive structures is comprised of Silicon Germanium (SiGe).

6. The nanowire MOSFET of claim 1, wherein the plurality of nanowire structures is comprised of a different material from the plurality of conductive structures.

7. The nanowire MOSFET of claim 1, wherein the plurality of nanowire structures is comprised of a material consisting of Silicon (Si), Silicon Germanium (SiGe), and a III-V material.

8. The nanowire MOSFET of claim 1, wherein the plurality of conductive structures is comprised of a material consisting of Silicon (Si), Silicon Germanium (SiGe), and a III-V material.

9. The nanowire MOSFET of claim 1, wherein the plurality of nanowire structures is comprised of a first material comprising Silicon (Si), and the plurality of conductive structures is comprised of a second material comprising Silicon Germanium (SiGe).

10. The nanowire MOSFET of claim 1, wherein the channel body further comprises at least one interfacial layer disposed adjacent to the nanowire channel structure.

11. The nanowire MOSFET of claim 1, wherein the channel body further comprises at least one dielectric material layer disposed adjacent to the nanowire channel structure.

12. The nanowire MOSFET of claim 11, wherein the channel body further comprises at least one gate work function material disposed adjacent to the at least one dielectric material layer.

13. The nanowire MOSFET of claim 1, wherein the channel body further comprises a gate material disposed adjacent to the nanowire channel structure.

14. The nanowire MOSFET of claim 1, further comprising:
a drain disposed above the substrate, the drain conductively coupled to the channel body; and
a source disposed above the substrate, the source conductively coupled to the channel body opposite the drain;
the nanowire channel structure configured to be activated in response to a voltage exceeding a defined threshold voltage applied across a gate and the source to form a channel between the source and the drain to carry a current between the source and the drain.

15. The nanowire MOSFET of claim 1 integrated into an integrated circuit (IC).

16. The nanowire MOSFET of claim 1 integrated into a radio-frequency (RF) IC (RFIC).

17. The nanowire MOSFET of claim 1 integrated into a device selected from the group consisting of: a set top box; an entertainment unit; a navigation device; a communications device; a fixed location data unit; a mobile location data unit; a mobile phone; a cellular phone; a smart phone; a tablet; a phablet; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; and an automobile.

18. A nanowire metal-oxide semiconductor (MOS) Field-Effect Transistor (FET) (MOSFET), comprising:
a means for providing a substrate; and
a means for providing a nanowire channel disposed about the means for providing a substrate, the means for providing the nanowire channel comprising:
a means for providing a plurality of conductive channel paths arranged in a vertically stacked arrangement about the means for providing the substrate, each of the plurality of conductive channel paths having a width about a width axis; and
a means adjacent to and recessed about the width axis from each of the means for providing the plurality of conductive channel paths for conductively coupling the means for providing the plurality of conductive channel paths.

19. A method of fabricating a nanowire metal-oxide semiconductor (MOS) Field-Effect Transistor (FET) (MOSFET), comprising:
forming a MOSFET comprising:
forming a substrate; and
forming a nanowire channel structure on the substrate, comprising:
forming a plurality of material layers comprising a plurality of first material layers comprising a plurality of nanowire structures each of a first width about a width axis and a plurality of second material layers comprising a plurality of conductive structures each of the first width and interdisposed between and adjacent to the plurality of first material layers; and
removing a plurality of regions in the plurality of second material layers along the width axis to recess the plurality of second material layers about the width axis from the plurality of first material layers, to recess the plurality of conductive structures from the plurality of nanowires structures.

20. The method of claim 19, comprising etching a plurality of trenches comprising removing the plurality of trenches in the plurality of second material layers along the width axis to recess the plurality of second material layers between 1 and 30 nanometers (nm) about the width axis from the plurality of first material layers to recess the plurality of conductive structures from the plurality of nanowires structures.

21. The method of claim 19, wherein the plurality of second material layers comprises a different etch sensitivity from the plurality of first material layers.

22. The method of claim 20, wherein removing the plurality of trenches comprises etching the plurality of trenches in the plurality of second material layers along the width axis to recess the plurality of second material layers about the width axis from the plurality of first material layers to recess the plurality of conductive structures from the plurality of nanowires structures.

23. The method of claim 22, wherein etching the plurality of trenches comprises exposing the plurality of second material layers to a wet chemical for a predetermined period of time to recess the plurality of second material layers about the width axis from the plurality of first material layers to recess the plurality of conductive structures from the plurality of nanowires structures.

24. The method claim 19, further comprising disposing at least one dielectric material layer disposed adjacent to the nanowire channel structure.

25. The method of claim 24, further comprising disposing at least one gate work function material disposed adjacent to the at least one dielectric material layer.

26. The method of claim 19, further comprising disposing a gate material adjacent to the nanowire channel structure to form a gate.

27. The method of claim 19, further comprising:
disposing a drain above the substrate conductively coupled to a first end of a channel body; and
disposing a source above the substrate conductively coupled to a second end of the channel body opposite the first end.

28. The method of claim 19, wherein the plurality of nanowire structures is comprised of a different material from the plurality of conductive structures.

29. The method of claim 19, wherein the plurality of nanowire structures is comprised of a material consisting of Silicon (Si), Silicon Germanium (SiGe), and a III-V material, and the plurality of conductive structures is comprised of a material consisting of Silicon (Si), Silicon Germanium (SiGe), and a III-V material.

30. The method claim 19, wherein the plurality of nanowire structures is comprised of a first material comprising Silicon (Si), and the plurality of conductive structures is comprised of a second material comprising Silicon Germanium (SiGe).
